(19) United States
(12) Patent Application Publication
(10) Pub. No.: US 2007/0032077 A1
(43) Pub. Date: Feb. 8, 2007

(54) METHOD OF MANUFACTURING METAL PLUG AND CONTACT

(76) Inventors: Tzung-Yu Hung, Tainan County (TW); Chien-Chung Huang, Taichung Hsien (TW); Chao-Ching Hsieh, Hsinchu Hsien (TW); Chia-Lin Hsu, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,530

(22) Filed: Aug. 8, 2005

(51) Int. Cl. H01L 21/44

(52) U.S. Cl. 438/672

(57) ABSTRACT

A method for manufacturing a metal plug is described. A substrate with an opening is provided. Then, a barrier layer is formed on a surface of the opening. Thereafter, a metallic layer is formed over the substrate so that the opening is also filled. Next, a planarization process is performed to remove the metallic layer outside the opening. One main feature of the present invention is the performance of at least a high temperature treatment after the metallic layer is formed. Due to the high temperature treatment, internal stress between different layers is released.

### BACKGROUND OF THE INVENTION

1. Field of the Invention

The present invention relates to a method of manufacturing metallic interconnects. More particularly, the present invention relates to a method of manufacturing a metal plug and a contact.

2. Description of the Related Art

With the continuous miniaturization of semiconductor devices, all kinds of high-speed multi-functional ultra large-scale integrated circuit chips are produced. However, as the semiconductor are miniaturized, the level of integration and hence the number of interconnecting wires has to be increased. With the increase in interconnecting wires, the surface of a chip can no longer accommodate all of them. To resolve this problem, a multiple metallic interconnect structure has been developed for manufacturing such complicated integrated circuits.

At present, the most commonly used metal plugs is tungsten plugs fabricated in a chemical vapor deposition process. Tungsten plugs have superior step coverage, high melting point and acceptable level of electrical conduction. Moreover, the tungsten plugs are easy to produce. All that is required is to form a contact opening or a via opening in a substrate in a dry etching process and then fill the opening with the metallic material.

However, as device miniaturization continues, the dimension of the metal plug is also reduced. Thus, the research on a method that can counteract the increase in resistance in a metal plug as a result of miniaturization is now actively pursued.

### SUMMARY OF THE INVENTION

Accordingly, at least one objective of the present invention is to provide a method for manufacturing a metal plug capable of reducing not only the internal stress between different material layers to facilitate subsequent processes but also the resistance of the metal plug.

At least a second objective of the present invention is to provide a method for manufacturing a contact capable of reducing the probability of producing a key hole in the contact, increasing electrical conductivity and enhancing device reliability.

To achieve these and other advantages and in accordance with the purpose of the invention, as embodied and broadly described herein, the invention provides a method for manufacturing a metal plug. First, a substrate having at least an opening is provided. Then, a barrier layer is formed on a surface of the opening. Thereafter, a metallic layer is formed over the substrate such that the opening is completely filled. A planarization process is carried out to remove the metallic layer outside the opening. One feature of the present invention is that at least a high-temperature treatment is performed after the metallic layer is formed over the substrate.

According to one embodiment of the fabrication method for a metal plug of the present invention, the above high-temperature treatment is performed between a temperature of 400 to 780 degrees Celsius. Further, another high-temperature treatment may also perform after the substrate is provided and before the barrier layer is formed on the surface of the opening. Yet another high-temperature treatment may also perform before the metallic layer is formed over the substrate and after the barrier layer is formed over the surface of the opening.

In one preferred embodiment of the present invention, the high-temperature treatment in the aforementioned method of manufacturing the metal plug includes a furnace treatment, an annealing operation or a rapid thermal process.

In one preferred embodiment of the present invention, the aforementioned step of forming a barrier layer on the surface of the opening includes forming a titanium layer over the surface of the opening and then forming a titanium nitride layer over the titanium layer. The metallic layer is fabricated using tungsten, for example.

The present invention also provides a method for manufacturing a contact. The method includes a. providing a substrate; b. forming a dielectric layer over the substrate; forming a contact opening in the dielectric layer; d. forming a barrier layer inside the contact opening; e. forming a metallic layer over the substrate so that the contact opening is completely filled; and f. carrying out a planarization process of the metallic layer to form a contact inside the contact opening. One major feature of the present method is that after the above step e, at least a high-temperature treatment is performed.

According to an embodiment of the present invention, the above high-temperature treatment is performed between a temperature of 400 to 780 degrees Celsius. Further, after step a and before step b, another high-temperature treatment may also perform. Additionally, after step b and before step c, another high-temperature treatment may also perform.

According to the preferred embodiment of the present invention, the high-temperature treatment in the method of manufacturing the contact includes a furnace treatment, an annealing operation or a rapid thermal process.

According to the preferred embodiment of the present invention, the step of forming a barrier layer inside the contact opening in the method of manufacturing the contact includes forming a titanium layer over the surface of the contact opening and then forming a titanium nitride layer over the titanium layer. The metallic layer is fabricated using tungsten, for example.

In the present invention, at least a high-temperature treatment is carried out after the metallic layer is formed over the substrate to completely fill the contact opening. Hence, with the reduction of overall thermal budget as the foremost consideration, dislocations and the density of defects in the substrate are reduced and the internal stress is modified to enhance the strength, the density and electrical performance of the plug. In addition, the present invention also reduces the probability of forming a keyhole in the plug and hence increases the conductivity of the plug through the high-temperature treatment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow diagram showing the steps for manufacturing a metal plug according to one preferred embodiment of the present invention.

FIGS. 2A through 2D are schematic cross-sectional views showing the steps for fabricating a contact according to another preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

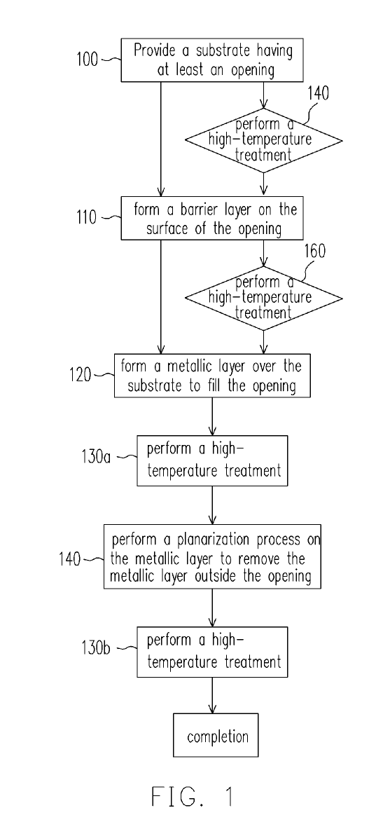

FIG. 1 is a flow diagram showing the steps for manufacturing a metal plug according to one preferred embodiment of the present invention. As shown in FIG. 1, the method in the present embodiment can be applied to a multiple metallic interconnecting processes or any other processes that demand to form a metal plug in a semiconductor structure such as a trench type capacitor. The method of fabricating the metal plug according to the present embodiment includes the following steps. Typically, step 100 is first performed in which a substrate having at least an opening is provided. The substrate can be a silicon wafer having a dielectric layer, for example, an inter-metal dielectric (IMD) or an inter-layer dielectric (ILD) formed thereon. The aforementioned opening is formed, for example, by performing a dry etching process.

Thereafter, a barrier layer is formed on the surface of the opening. The barrier layer is formed, for example, by forming a titanium layer over the surface of the opening and then forming a titanium nitride layer over the titanium layer. The method of forming the titanium layer and the titanium nitride layer includes, for example, a nitridation reaction or a reactive sputtering process or a metal-organic chemical vapor deposition (MOCVD).

Afterwards, in step 120, a metallic layer is formed over the substrate so that the opening is also completely filled. The metallic layer is fabricated using a material such as aluminum or tungsten, preferably tungsten. The method of forming the metallic layer includes performing a chemical vapor deposition process, for example.

In step 130, a high-temperature treatment is carried out on the metallic layer for the size of the crystal grains in the barrier layer be more uniformed and the surface be smoother and denser so that the internal stress between the metallic layer and the barrier layer can be improved. More particularly, the high-temperature treatment is conducted between 400 to 780 degrees Celsius, and the high-temperature treatment includes a t furnace treatment, an anneal operation or a rapid thermal annealing operation.

Thereafter, in step 140, a planarization process is performed on the metallic layer to remove the metallic layer outside the opening, wherein the planarization process includes a chemical-mechanical polishing operation, for example.

Moreover, after step 140, step 130b may again perform so that the surface of the metallic layer can be smoother and denser to facilitate the deposition of the subsequent material layer. In summary, at least a high-temperature treatment is performed after step 120 to generate desirable effects on the metallic layer.

In addition, if an additional high-temperature treatment (step 140) is performed between step 100 and step 110, the sizes of the crystal grains at the bottom of the opening and the sidewall are consistent. Accordingly, the surface of the metallic layer can be smoother and denser to facilitate the deposition of the subsequent material layer. Further, a high-temperature treatment (step 160) may also incorporate between step 110 and step 120 to normalize the size of the crystal grains in the barrier layer.

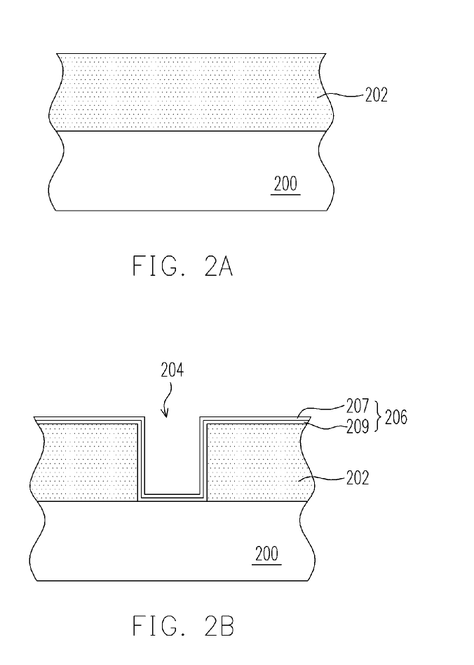

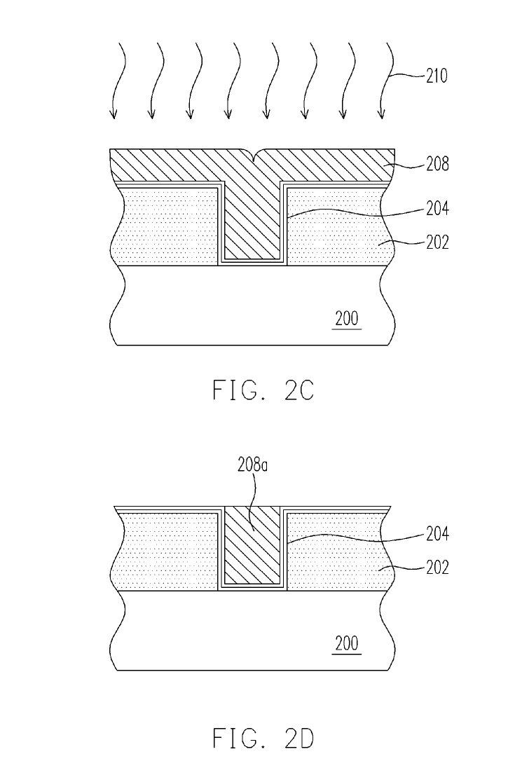

FIGS. 2A through 2D are schematic cross-sectional views showing the steps for fabricating a contact according to another preferred embodiment of the present invention. As shown in FIG. 2A, a substrate 200 is provided. Then, a dielectric layer 202 is formed over the substrate 200. Thereafter, a high-temperature treatment is performed or the next processing step is carried out directly.

As shown in FIG. 2B, a contact opening 204 is formed in the dielectric layer 202 and then a barrier layer 206 is formed inside the contact opening 204. The method of forming the barrier layer 206 inside the contact opening 204 includes forming a titanium layer 209 over the surface of the contact opening 204 and then forming a titanium nitride layer 207 over the titanium layer 209. Thereafter, another high-temperature treatment is performed or the next processing step is carried out directly.

As shown in FIG. 2C, a metallic layer 208 is formed over the substrate 200 to fill the contact opening 208 completely. The method of forming the metallic layer 208 includes, for example, performing a chemical vapor deposition process. The metallic layer is fabricated using tungsten, for example. Thereafter, a high-temperature treatment 210 is carried out on the metallic layer 209 to increase crystal grain uniformity inside the metallic layer, smoothness and compactness of its surface and reduce internal stress between the metallic layer 208 and the barrier layer 206. Hence, the probability of having a keyhole in the metal plug is reduced. Ultimately, the resistance of the metal plug is reduced and the reliability of the device is enhanced.

As shown in FIG. 2D, the metallic layer 208 is planarized to form a contact 208a inside the contact opening 204. The method of planarizing the metallic layer 208 includes performing a chemical-mechanical polishing operation, for example. Thereafter, another high-temperature treatment can be carried out selectively.

In summary, major characteristics of the present invention at least include the followings.

1. At least a high-temperature treatment is performed after the formation of the metallic layer that dislocations and density of defects in various material are significantly reduced. Thus, subsequent processing operations are facilitated and devices having high electrical performance are produced.

2. The high-temperature treatment in the present invention is able to reduce the probability of forming a keyhole in the metal plug. Hence, the resistance of the metal plug is reduced and the reliability of the device is enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a metal plug, comprising the steps of:
providing a substrate having at least an opening;
forming a barrier layer on a surface of the opening;
forming a metallic layer over the substrate to fill the opening; and
performing a planarization process on the metallic layer to remove the metallic layer outside the opening, wherein
after the step of forming of the metallic layer over the substrate, at least a first high-temperature treatment is performed.

2. The method of claim 1, wherein the first high-temperature treatment is conducted between 400 to 780 degrees Celsius.

3. The method of claim 1, wherein the first high-temperature treatment includes a furnace treatment, an anneal operation or a rapid thermal annealing operation.

4. The method of claim 1, wherein, the high-temperature treatment is performed after the metallic layer is formed over the substrate to fill the opening and before the planarization process is performed on the metallic layer to remove the metallic layer outside the opening.

5. The method of claim 1, wherein the first high-temperature is performed after the planarization process is performed on the metallic layer.

6. The method of claim 1, wherein after providing the substrate but before forming the barrier layer on the surface of the opening, further comprises performing a second high-temperature treatment.

7. The method of claim 6, wherein the second high-temperature treatment includes a hot furnace treatment, an anneal operation or a rapid thermal annealing operation.

8. The method of claim 1, wherein after forming the barrier layer on the surface of the opening but before forming the metallic layer over the substrate, further comprises performing a third high-temperature treatment.

9. The method of claim 8, wherein the third high-temperature treatment includes a hot furnace treatment, an anneal operation or a rapid thermal annealing operation.

10. The method of claim 1, wherein the step of forming the barrier layer on the surface of the opening further comprising:
forming a titanium layer over the surface of the opening; and
forming a titanium nitride layer over the titanium layer.

11. The method of claim 1, wherein the step of forming the metallic layer comprises performing a chemical vapor deposition process.

12. The method of claim 11, wherein the material constituting the metallic layer comprises tungsten.

13. The method of claim 1, wherein the step of planarizing the metallic layer comprises performing a chemical-mechanical polishing process.

14. A method of manufacturing a contact, comprising the steps of:
a. providing a substrate;
b. forming a dielectric layer over the substrate;
c. forming a contact opening in the dielectric layer;
d. forming a barrier layer inside the contact opening;
e. forming a metallic layer over the substrate to fill the contact opening; and
f. planarizing the metallic layer to form a contact inside the contact opening, wherein at least a first high-temperature treatment is performed after the step e.

15. The method of claim 14, wherein the first high-temperature treatment is conducted between 400 to 780 degrees Celsius.

16. The method of claim 14, wherein the first high-temperature treatment includes a furnace treatment, an anneal operation or a rapid thermal annealing operation.

17. The method of claim 14, wherein the first high-temperature treatment is conducted after the step e and before the step f.

18. The method of claim 14, wherein the first high-temperature treatment is conducted after the step f.

19. The method of claim 14 further comprising a second high-temperature treatment performed between the step c and the step d.

20. The method of claim 19, wherein the second high-temperature treatment includes a furnace treatment, an anneal operation or a rapid thermal annealing operation.

21. The method of claim 14, further comprising a third high-temperature treatment performed between the step d and the step e.

22. The method of claim 21, wherein the third high-temperature treatment includes a furnace treatment, an annealing operation or a rapid thermal annealing operation.

23. The method of claim 14, wherein the step of forming the barrier layer inside the contact opening comprises:
forming a titanium layer on a surface of the contact opening; and
forming a silicon nitride layer over the titanium layer.

24. The method of claim 14, wherein the step of forming the metallic layer over the substrate comprises performing a chemical vapor deposition process.

25. The method of claim 24, wherein the material constituting the metallic layer comprises tungsten.

26. The method of claim 14, wherein the step of planarizing the metallic layer includes performing a chemical-mechanical polishing operation.
